(19) United States
(12) Patent Application Publication
(10) Pub. No.: US 2011/0297216 A1
(43) Pub. Date: Dec. 8, 2011

(54) ORGANIC SOLAR CELL AND METHOD OF MANUFACTURING THE SAME

(75) Inventors: Soo-Ghang IHN, Hwaseong-si (KR); Kil-Won CHO, Pohang-si (KR); Ji-Hwang LEE, Pohang-si (KR); Sae-Byeok JO, Pohang-si (KR)

(73) Assignees: POSTECH ACADEMY-INDUSTRY FOUNDATION, Pohang-city (KR); SAMSUNG ELECTRONICS CO., LTD., Suwon-si (KR)

(21) Appl. No.: 12/942,653

(22) Filed: Nov. 9, 2010

(30) Foreign Application Priority Data
Jun. 7, 2010 (KR) 10-2010-0053259

(51) Int. Cl. H01L 51/44; H01L 31/18; H01L 31/10; B82Y 30/00

(52) U.S. Cl. 136/255; 438/57; 257/E31.001; 977/773

(57) ABSTRACT

An organic solar cell includes an anode and a cathode facing each other, a photoactive layer disposed between the anode and the cathode and including an electron donor and an electron acceptor, and a transparent auxiliary layer disposed between the anode and the cathode and in contact with the photoactive layer. The transparent auxiliary layer includes inorganic nanoparticles and a polymer.

### CROSS-REFERENCE TO RELATED APPLICATION

This application claims priority to Korean Patent Application No. 10-2010-0053259 filed on Jun. 7, 2010, and all the benefits accruing therefrom under 35 U.S.C. §119, the entire contents of which is incorporated herein by reference.

### BACKGROUND

1. Field

Provided is an organic solar cell and a method for manufacturing the same.

2. Description of the Related Art

A solar cell is a photoelectric conversion device that transforms solar energy into electrical energy, and has attracted much attention as an infinite but pollution-free next-generation energy source.

A solar cell includes p-type and n-type semiconductors and produces electrical energy by transferring electrons and holes to the n-type and p-type semiconductors, respectively, and then collecting electrons and holes in each electrode when an electron-hole pair (“EHP”) is produced by solar light energy absorbed in a photoactive layer inside the semiconductors.

A solar cell is required to have as much efficiency as possible for producing electrical energy from solar energy. The organic solar cell may be classified into a bi-layer p-n junction structure in which a p-type semiconductor is formed in a separate layer from an n-type semiconductor, and a bulk heterojunction structure in which a p-type semiconductor is mixed with an n-type semiconductor.

### SUMMARY

Provided is an organic solar cell that may improve efficiency by increasing light absorption, a fill factor, and an open circuit voltage (“Voc”), and may simplify a manufacturing process thereof.

Provided is a method of manufacturing the organic solar cell.

Provided is an organic solar cell that includes an anode and a cathode facing each other, a photoactive layer disposed between the anode and the cathode and including an electron donor and an electron acceptor, and a transparent auxiliary layer disposed between the anode and the cathode and in contact with the photoactive layer. The transparent auxiliary layer includes inorganic nanoparticles and a polymer.

The polymer may include an insulating polymer.

The polymer may include polyethylene glycol (“PEG”), polyethylene oxide (“PEO”), or a combination thereof.

The inorganic nanoparticles may include one selected from the group consisting of a metal oxide, a semiconductor compound, and a combination thereof.

The inorganic nanoparticles may include one selected from the group consisting of zinc oxide, titanium oxide, tantalum oxide, tin oxide, niobium oxide, zirconium oxide, lanthanum oxide, copper oxide, strontium oxide, indium oxide, molybdenum oxide, vanadium oxide, tungsten oxide, nickel oxide, iridium oxide, sodium titanate, cadmium sulfide, indium antimonide, gallium antimonide, aluminum antimonide, indium arsenide, gallium arsenide, aluminum arsenide, cadmium selenide, lead sulfide, indium phosphide, gallium phosphide, aluminum phosphide, cadmium telluride, tellurium cadmium, and a combination thereof.

The transparent auxiliary layer contacts the anode, and the inorganic nanoparticles may include one selected from the group consisting of molybdenum oxide, vanadium oxide, tungsten oxide, nickel oxide, iridium oxide, lanthanum oxide, copper oxide, strontium oxide, indium oxide, and a combination thereof.

The transparent auxiliary layer contacts the cathode, and the inorganic nanoparticles may include one selected from the group consisting of zinc oxide, titanium oxide, tantalum oxide, tin oxide, niobium oxide, cadmium sulfide, lead sulfide, indium antimonide, gallium antimonide, aluminum antimonide, cadmium selenide, cadmium telluride, gallium arsenide, aluminum arsenide, indium phosphide, gallium phosphide, aluminum phosphide, and a combination thereof.

An inorganic nanoparticle may have a smaller size than a thickness of the transparent auxiliary layer.

The transparent auxiliary layer may include a first transparent auxiliary layer including the inorganic nanoparticles, and a second transparent auxiliary layer including the polymer.

The transparent auxiliary layer may be a monolayer including the inorganic nanoparticles and the polymer.

A first surface of the transparent auxiliary layer may be in contact with the photoactive layer, and a second surface opposing the first surface of the transparent auxiliary layer may be in contact with the anode or the cathode.

The organic solar cell may further include a buffer layer disposed between the photoactive layer and the anode or the cathode.

The buffer layer may include a conductive polymer.

The photoactive layer may include a first photoactive layer and a second photoactive layer, and the transparent auxiliary layer may be disposed between the first photoactive layer and the second photoactive layer.

Provided is an organic solar cell that includes a first electrode, a buffer layer disposed on a surface of the first electrode and including a conductive polymer, a photoactive layer disposed on a surface of the buffer layer, a first transparent auxiliary layer disposed on a surface of the photoactive layer and including inorganic nanoparticles and an insulating polymer, and a second electrode disposed on a surface of the first transparent auxiliary layer.

The conductive polymer may include one selected from the group consisting of poly(3,4-ethylenedioxythiophene): polystyrene sulfonate (“PEDOT:PSS”), polypyrrole, or a combination thereof, and the insulating polymer may include polyethylene glycol (“PEG”), polyethylene oxide (“PEO”), and a combination thereof.

The photoactive layer may include a first photoactive layer and a second photoactive layer. The organic solar cell may further include a second transparent auxiliary layer disposed between the first photoactive layer and the second photoactive layer, and including the inorganic nanoparticles and the insulating polymer.

Provided is a method of manufacturing an organic solar cell. The method includes providing a first electrode, providing a photoactive layer on a surface of the first electrode, providing a transparent auxiliary layer including inorganic nanoparticles and a polymer on a surface of the photoactive layer, and providing a second electrode on a surface of the transparent auxiliary layer.

The polymer may include an insulating polymer.

The transparent auxiliary layer may be formed according to a solution process.

The providing a transparent auxiliary layer may include providing the inorganic nanoparticles on the surface of the photoactive layer, and separately providing the polymer on the inorganic nanoparticle.

The providing a transparent auxiliary layer may include providing a solution including both the inorganic nanoparticles and the polymer on a surface of the photoactive layer.

### BRIEF DESCRIPTION OF THE DRAWINGS

The above an other features of this disclosure will become more apparent by describing in further detail embodiments thereof with reference to the accompanying drawings, in which:

FIG. 1 is a cross-sectional view of an embodiment of an organic solar cell, according to the inventions.

FIG. 2A is a cross-sectional view showing an embodiment of a transparent auxiliary layer in a bi-layer in the organic solar cell shown in FIG. 1.

FIG. 2B is a cross-sectional view showing an embodiment of a transparent auxiliary layer in a monolayer in the organic solar cell shown in FIG. 1.

FIG. 3 is a cross-sectional view showing another embodiment of an organic solar cell, according to the invention.

FIG. 4 is a graph showing a current characteristic of the organic solar cells, according to Examples 1 and 2, and Comparative Examples 1 to 4.

FIG. 5 is a graph showing light absorption and external quantum efficiency of the organic solar cell according to Example 1, compared to the organic solar cell according to Comparative Example 1.

### DETAILED DESCRIPTION

Embodiments will hereinafter be described in detail referring to the following accompanied drawings, and can be easily performed by those who have common knowledge in the related art. However, these embodiments are exemplary, and the present invention is not limited thereto.

In the drawings, the thickness of layers, films, panels, regions, etc., are exaggerated for clarity. Like reference numerals designate like elements throughout the specification. As used herein, the term “and/or” includes any and all combinations of one or more of the associated listed items.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

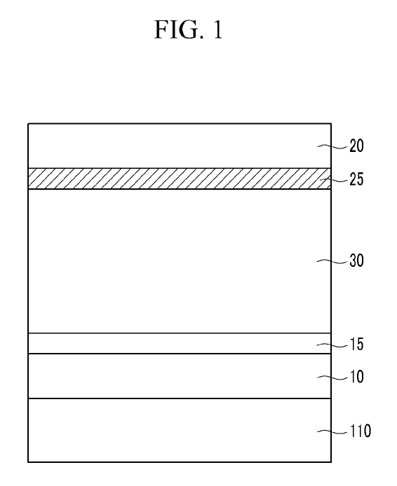

Referring to FIG. 1, an organic solar cell, according to the invention is illustrated.

FIG. 1 is a cross-sectional view of an embodiment of an organic solar cell, according to the invention.

As shown in FIG. 1, the organic solar cell includes a substrate 110, a lower electrode 10 disposed on one surface of the substrate 110, a buffer layer 15 disposed on one surface of the lower electrode 10, a photoactive layer 30 disposed on one surface of the buffer layer 15, a transparent auxiliary layer 25 disposed on one surface of the photoactive layer 30, and an upper electrode 20 disposed on one surface of the transparent auxiliary layer 25.

The substrate 110 may include a light-transmittable material, for example, an inorganic material such as glass, or an organic material such as polycarbonate, polymethyl methacrylate, polyethylene terephthalate, polyethylene naphthalate, polyamide, and polyether sulfone.

Either the lower electrode 10 or the upper electrode 20 is an anode, and the other electrode is a cathode. Either the lower electrode 10 or the upper electrode 20 may include a transparent conductor such as indium tin oxide (“ITO”), indium zinc oxide (“IZO”), tin oxide (SnO₂), aluminum doped zinc oxide (“AZO”), and gallium doped zinc oxide (“GZO”), and the other electrode may include an opaque conductor such as aluminum (Al), silver (Ag), gold (Au), lithium (Li), or the like.

The buffer layer 15 is a layer that is capable of effectively transporting or blocking electric charges. In one embodiment, for example, the buffer layer 15 may be a hole transport layer (“HTL”) or an electron blocking layer if the lower electrode 10 is an anode.

The buffer layer 15 may include a conductive polymer and may include, for example, poly(3,4-ethylene dioxythiophene):polystyrene sulfonate (“PEDOT:PSS”), polypyrrole, or a combination thereof.

The photoactive layer 30 includes an electron acceptor and an electron donor. The electron acceptor includes an n-type semiconductor material, and the electron donor includes a p-type semiconductor material.

The electron acceptor may include, for example, fullerene (C60, C70, C74, C76, C78, C82, C84, C720, C860, or the like) having a high electron affinity, a fullerene derivative such as 1-(3-methoxy-carbonyl)propyl-1-phenyl 6 and 6C61 (1-(3-methoxy-carbonyl)propyl-1-phenyl 6 and 6C61: PCBM), C71-PCBM, C84-PCBM, bis-PCBM or the like, perylene, an inorganic semiconductor such as CdS, CdTe, CdSe, or ZnO, or a combination thereof.

The electron donor may include, for example, polyaniline, polypyrrole, polythiophene, poly(p-phenylene vinylene), poly[2-methoxy-5-(2′-ethyl-hexyloxy)-1,4-phenylene vinylene (“MEH-PPV”), poly(2-methoxy-5-(3,7-dimethyloctyloxy)-1,4-phenylene-vinylene) (“M DMO-PPV”), pentacene, poly(3,4-ethylenedioxythiophene) (“PEDOT”), poly(3-alkylthiophene) such as poly(3-hexylthiophene) (“P3HT”), or a combination thereof.

The electron acceptor and the electron donor may form, for example, a bulk heterojunction structure. In the bulk heterojunction structure, the electron-hole pair is excited by light absorbed in the photoactive layer 30, and diffused to reach the interface between an electron acceptor and an electron donor. The electron-hole pair then it is separated into an electron and a hole, due to the electron affinity difference between the two materials for the interface. The electron is transported into a cathode through the electron acceptor, and the hole is transported into an anode through the electron donor, to generate a photocurrent.

The transparent auxiliary layer 25 is in contact with the photoactive layer 30, and may effectively control an electric charge transporting from the photoactive layer 30 to the upper electrode 20. In one embodiment, for example, if the upper electrode 20 is a cathode, it may increase the electron mobility from the photoactive layer 30 to the upper electrode 20, and block the hole to prevent the lost of electrons and holes by the recombination thereof in the upper electrode 20 side.

In addition, the transparent auxiliary layer 25 may increase the light amount incident to the photoactive layer 30. In one embodiment, for example, the light incident from the substrate 110 has very low light intensity in the vicinity of the upper electrode 20. In this case, the part in contact with the upper electrode 20 also decreases the light intensity. According to one embodiment, the transparent auxiliary layer 25 may increase the light amount incident into the photoactive layer 30 without affecting the upper electrode 20, by disposing the transparent auxiliary layer 25 in contact with the upper electrode 20 and providing the photoactive layer 30 apart from the upper electrode 20 by a predetermined distance. Accordingly, the transparent auxiliary layer 25 may increase the light efficiency of an organic solar cell.

The transparent auxiliary layer 25 may have a thickness taken in a direction perpendicular to the substrate 110, of about 1 nanometer (nm) to about 50 nanometers (nm).

The transparent auxiliary layer 25 may include inorganic nanoparticle material and a polymer.

The inorganic nanoparticle material of the transparent auxiliary layer 25 is not specifically limited, as long as it is an inorganic semiconductor material capable of controlling the electric charge mobility. If the upper electrode 20 is a cathode, the inorganic nanoparticle material may be a material having high electron mobility and a hole blocking property. Alternatively, if the upper electrode 20 is an anode, the inorganic nanoparticle material may be a material having high hole mobility and an electron blocking property.

The inorganic nanoparticle material of the transparent auxiliary layer 25 may include, for example, a metal oxide, a semiconductor compound, or a combination thereof. In embodiments, examples of the inorganic nanoparticle material may include zinc oxide, titanium oxide, tantalum oxide, tin oxide, niobium oxide, zirconium oxide, lanthanum oxide, copper oxide, strontium oxide, indium oxide, molybdenum oxide, vanadium oxide, tungsten oxide, nickel oxide, iridium oxide, sodium titanate, cadmium sulfide, indium antimonide, gallium antimonide, aluminum antimonide, indium arsenide, gallium arsenide, aluminum arsenide, cadmium selenide, lead sulfide, indium phosphide, gallium phosphide, aluminum phosphide, cadmium telluride, tellurium cadmium, or a combination thereof.

When the transparent auxiliary layer 25 is in contact with an anode, the inorganic nanoparticle material may include molybdenum oxide, vanadium oxide, tungsten oxide, nickel oxide, iridium oxide, lanthanum oxide, copper oxide, strontium oxide, indium oxide, or a combination thereof.

Alternatively, when the transparent auxiliary layer 25 is in contact with a cathode, the inorganic nanoparticle material may include zinc oxide, titanium oxide, tantalum oxide, tin oxide, niobium oxide, cadmium sulfide, lead sulfide, indium antimonide, gallium antimonide, aluminum antimonide, cadmium selenide, cadmium telluride, gallium arsenide, aluminum arsenide, indium phosphide, gallium phosphide, aluminum phosphide, or a combination thereof.

The inorganic nanoparticle material of the transparent auxiliary layer 25 may include inorganic nanoparticles. The nanoparticles may have a smaller particle size than the thickness of the transparent auxiliary layer 25. In one embodiment, for example, a nanoparticle may have a size of about 1 nm to about 50 nm.

The polymer of the transparent auxiliary layer 25 may include an insulating polymer having a high band gap that expresses an insulating property. The insulating polymer may increase an open circuit voltage (“Voc”) and a fill factor (“FF”) of an organic solar cell, by decreasing the generation of voids between inorganic nanoparticles. In addition, the insulating polymer may decrease current leakage due to the inorganic nanoparticles and play a role of passivation.

In embodiments, examples of the insulating polymer may include, for example, polyethylene glycol (“PEG”), polyethylene oxide (“PEO”), or a combination thereof.

The transparent auxiliary layer 25 includes a bi-layer structure, including a lower transparent auxiliary layer including inorganic nanoparticles, and an upper transparent auxiliary layer including a polymer. In addition, the transparent auxiliary layer 25 may include a monolayer structure in which the inorganic nanoparticles are mixed with the polymer.

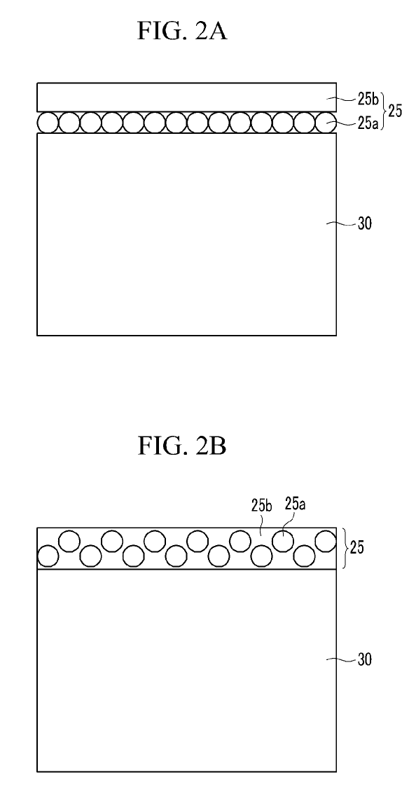

An embodiment of a method of manufacturing the organic solar cell will be described with reference to FIG. 1, FIG. 2A, and FIG. 2B.

FIG. 2A is a cross-sectional view showing an embodiment of the transparent auxiliary layer of a bi-layer structure in the organic solar cell shown in FIG. 1, and FIG. 2B is a cross-sectional view showing an embodiment of the transparent auxiliary layer of a monolayer structure in the organic solar cell shown in FIG. 1.

A lower electrode 10 is formed on the substrate 110. The lower electrode 10 may be formed by, for example, a sputtering process.

A buffer layer 15 is formed on the lower electrode 10. The buffer layer 15 may be coated in a form of a solution in which the conductive polymer is dissolved in a solvent, and dried.

A photoactive layer 30 is formed on the buffer layer 15. The photoactive layer 30 may also be formed in a solution.

Then a transparent auxiliary layer 25 is formed on the photoactive layer 30.

The transparent auxiliary layer 25 may be provided according to a solution process. The solution process may include, for example, spin coating, slit coating, inkjet printing, or the like. In this case, the inorganic nanoparticles and the polymer may be mixed in a solvent separately or simultaneously, and coated in a form of solution.

The usable solvent may one selected from, for example, deionized water, methanol, ethanol, propanol, 1-butanol, isopropanol, 2-methoxyethanol, 2-ethoxyethanol, 2-propoxyethanol 2-butoxyethanol, methylcellosolve, ethylcellosolve, diethylene glycol methylether, diethylene glycolethyl ether, dipropylene glycol methylether, toluene, xylene, hexane, heptane, octane, ethyl acetate, butyl acetate, diethylene glycol dimethylether, diethylene glycol dimethylethylether, methyl methoxy propionate, ethyl ethoxy propionate, ethyl lactate, propylene glycol methylether acetate, propylene glycol methylether, propylene glycol propylether, methylcellosolve acetate, ethylcellosolve acetate, diethylene glycol methylacetate, diethylene glycol ethylacetate, acetone, chloroform, methylisobutylketone, cyclohexanone, dimethyl formamide (“DMF”), N,N-dimethyl acetamide (“DMAc”), N-methyl-2-pyrrolidone, γ-butyrolactone, diethylether, ethylene glycol dimethylether, diglyme, tetrahydrofuran, chlorobenzene, dichlorobenzene, acetyl acetone, acetonitrile, and a combination thereof.

The transparent auxiliary layer 25 may be provided in a bi-layer or a monolayer structure, according to the manufacturing process. The bi-layer structure is described with reference to FIG. 2A, and the monolayer structure is described with reference to FIG. 2B.

Referring to FIG. 2A, a solution including a plurality of an inorganic nanoparticle 25a, is first directly coated on the photoactive layer 30 and dried. Then a solution including a polymer 25b is coated thereon, and dried to provide a bi-layer transparent auxiliary layer 25.

Further, referring to FIG. 2B, a solution including the inorganic nanoparticles 25a and a polymer 25b is directly coated on the photoactive layer 30 and dried, to provide a monolayer transparent auxiliary layer 25.

An upper electrode 20 is formed on the transparent auxiliary layer 25. The upper electrode 20 may be formed in accordance with, for example, a sputtering process.

According to one embodiment, the organic solar cell may have increased efficiency without using expensive vacuum deposition, by providing the transparent auxiliary layer 25 including inorganic nanoparticles and a polymer on the photoactive layer 30, according to a solution process. Accordingly, the solution process may simplify the process of manufacturing the organic solar cell and save cost.

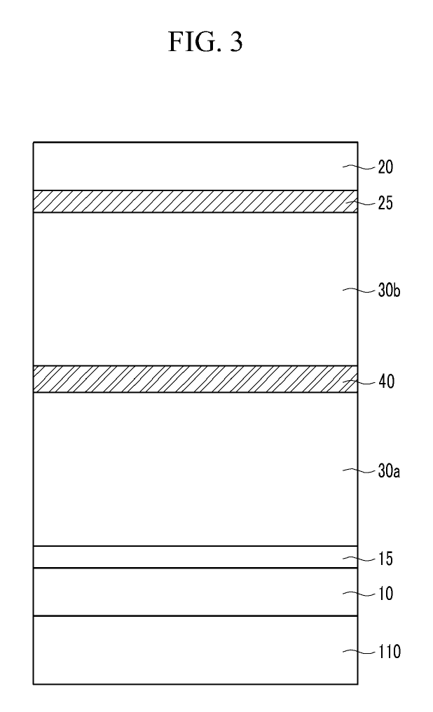

Hereinafter, another organic solar cell according to the invention is described with reference to FIG. 3. The same description as in the mentioned examples will be omitted.

FIG. 3 is a cross-sectional view showing another embodiment of an organic solar cell, according to the invention.

Referring to FIG. 3, the organic solar cell includes a substrate 110, a lower electrode 10 disposed on one surface of the substrate 110, a buffer layer 15 disposed on one surface of the lower electrode 10, a lower photoactive layer 30a disposed on one surface of buffer layer 15, a first transparent auxiliary layer 40 disposed on one surface of the lower photoactive layer 30a, an upper photoactive layer 30b disposed on one surface of the transparent auxiliary layer 40, a second transparent auxiliary layer 25 disposed on one surface of upper photoactive layer 30b, and an upper electrode 20 disposed on one surface of the transparent auxiliary layer 25.

The organic solar cell has a tandem structure, differing from the above-mentioned embodiment shown in FIG. 1. The tandem structure organic solar cell includes the lower photoactive layer 30a and the upper photoactive layer 30b between the lower electrode 10 and the upper electrode 20, and the first transparent auxiliary layer 40 between the lower photoactive layer 30a and the upper photoactive layer 30b. The first transparent auxiliary layer 40 may play a role of an interlayer between the two photoactive layers 30a and 30b, differing from the above-mentioned embodiment shown in FIG. 1.

The first transparent auxiliary layer 40 is in contact with both the lower photoactive layer 30a and the upper photoactive layer 30b, and may function to recombine electrons and holes between the lower photoactive layer 30a and the upper photoactive layer 30b. In one embodiment, for example, if the lower electrode 10 is an anode and the upper electrode 20 is a cathode, the hole produced from the lower photoactive layer 30a and the electron produced from the upper photoactive layer 30b are respectively transported into the lower electrode 10 and an upper electrode 20 to generate current. The electron produced from the lower photoactive layer 30a and the hole produced from the electron and upper photoactive layer 30b are respectively transported into the first transparent auxiliary layer 40 and may recombine to disappear. Thereby, the first transparent auxiliary layer 40 may reduce or effectively prevent the recombination and disappearance of electric charges by excessive electrons and holes in the vicinity of the lower electrode 10 or the upper electrode 20.

The first transparent auxiliary layer 40 includes inorganic nanoparticle material, including nanoparticles and a polymer, as in the transparent auxiliary layer 25 described with respect to FIG. 1.

The inorganic nanoparticle material of the first transparent auxiliary layer 40 is not limited as long as it is an inorganic semiconductor material capable of controlling the charge mobility. In one embodiment, for example, inorganic nanoparticle material of the first transparent auxiliary layer 40 may include a metal oxide, a semiconductor compound, or a combination thereof. In embodiments, examples of the inorganic nanoparticle material include zinc oxide, titanium oxide, tantalum oxide, tin oxide, niobium oxide, zirconium oxide, lanthanum oxide, copper oxide, strontium oxide, indium oxide, molybdenum oxide, vanadium oxide, tungsten oxide, nickel oxide, iridium oxide, sodium titanate, cadmium sulfide, indium antimonide, gallium antimonide, aluminum antimonide, indium arsenide, gallium arsenide, aluminum arsenide, cadmium selenide, lead sulfide, indium phosphide, gallium phosphide, aluminum phosphide, cadmium telluride, tellurium cadmium, and a combination thereof.

The polymer of the inorganic nanoparticle material of the first transparent auxiliary layer 40 may include an insulating polymer having a high affinity with inorganic nanoparticles and decreasing current leakage due to the inorganic nanoparticles. The insulating polymer includes for example polyethylene glycol (“PEG”), polyethylene oxide (“PEO”), or a combination thereof.

Hereinafter, the embodiments are illustrated in more detail with reference to examples. However, the following embodiments are exemplary and are not limiting of the invention.

### Fabricating Organic Solar Cell

### Example 1

ITO is laminated on a glass substrate and subsequently washed with each of detergent, distilled water, acetone, and isopropyl alcohol for 10 minutes in ultrasonic waves and dried. Poly(3,4-ethylene dioxythiophene):polystyrene sulfonate (“PEDOT:PSS”) is spin-coated on the ITO layer and dried. Then poly(3-hexylthiophene) (“P3HT”):fullerene derivative (“PCBM”) solution is coated and dried to provide a photoactive layer.

Polyethylene glycol and zinc oxide particles having a particle size of about 5 nm are mixed in a concentration of 1 milligram per milliliter (mg/ml) and 15 mg/ml, respectively in methanol and 1-butanol to provide a solution. The solution is spin-coated on the photoactive layer and dried to provide a transparent auxiliary layer which is a monolayer. An aluminum electrode is laminated on the transparent auxiliary layer.

### Example 2

ITO is laminated on a glass substrate and subsequently washed with each of distilled water, acetone, and isopropyl alcohol for 10 minutes in ultrasonic waves and dried. Poly(3,4-ethylene dioxythiophene):polystyrene sulfonate (“PEDOT:PSS”) is spin-coated on the ITO layer and dried. P3HT:fullerene derivative solution is coated and dried to provide a photoactive layer.

Each of a 1 mg/ml polyethylene glycol solution and a 15 mg/ml zinc oxide particle solution having a particle size of about 5 nm is prepared. The zinc oxide particle solution is first coated on the photoactive layer and dried, and then the polyethylene glycol solution is coated thereon and dried to provide a transparent auxiliary layer which is a bi-layer. Then an aluminum electrode is laminated on a transparent auxiliary layer.

### Comparative Example 1

An organic solar cell is fabricated in accordance with the same procedure as in Example 1, except that the transparent auxiliary layer is not provided.

### Comparative Example 2

An organic solar cell is fabricated in accordance with the same procedure as in Example 1, except that the transparent auxiliary layer is formed by using only polyethylene glycol without zinc oxide particles.

### Comparative Example 3

An organic solar cell is fabricated in accordance with the same procedure as in Example 1, except that the transparent auxiliary layer is formed by using only zinc oxide particles without polyethylene glycol.

### Comparative Example 4

An organic solar cell is fabricated in accordance with the same procedure as in Example 1, except that lithium fluoride (“LiF”) is vacuum deposited instead of polyethylene glycol and zinc oxide particles.

Evaluation

Current Characteristic

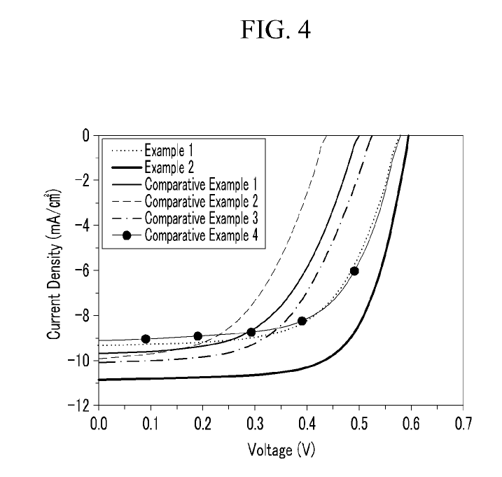

Organic solar cells obtained from Examples 1 and 2 and Comparative Examples 1 to 4 are described with regard to current characteristic with reference to FIG. 4.

FIG. 4 is a graph showing the current characteristic of organic solar cells according to Examples 1 and 2, and Comparative Examples 1 to 4. FIG. 4 illustrates current density in milliamps per square centimeter (mA/cm²) versus voltage in volts (V).

Referring to FIG. 4, the organic solar cells according to Examples 1 and 2 have a higher open circuit voltage (the voltage when the current is 0, Voc) and a higher fill factor (“FF”) (product of open circuit voltage and short circuit current) than the organic solar cells according to Comparative Examples 1 to 3.

Thereby, it is confirmed that the open circuit voltage and the fill factor are improved when the transparent auxiliary layer includes both the inorganic nanoparticles and the polymer.

On the other hand, the organic solar cell according to Example 2 has a similar open current voltage and fill factor to the organic solar cell according to Comparative Example 4 in which the transparent auxiliary layer includes fluorinated lithium formed by the vacuum deposition. It is understood that the organic solar cell according to Example 2 may simplify the process and save cost by using the solution process, and also has similar characteristics to the organic solar cell according to Comparative Example 4.

Light Efficiency

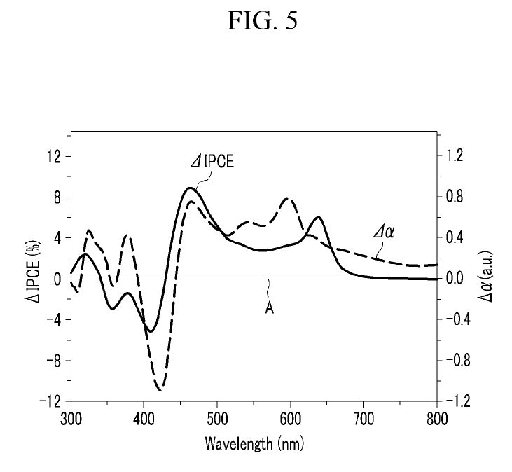

Referring to FIG. 5, the light absorption and external quantum efficiency of the organic solar cell according to Example 1, are observed compared to those of Comparative Example 1. FIG. 5 illustrates external quantum efficiency as a difference in incident photon to charge carrier efficiency (ΔIPCE) percentage (%) and changes in light absorption (Δα) in atomic units (a.u.), versus wavelength in nanometers (nm).

FIG. 5 is a graph showing the light absorption and external quantum efficiency of the organic solar cell according to Example 1 compared to those of Comparative Example 1.

FIG. 5 shows the external quantum efficiency and the light absorption of the organic solar cell according to Example 1 when the external quantum efficiency and light absorption of the organic solar cell according to Comparative Example 1 are referred to as “0” (indicated as line A).

Referring to FIG. 5, the organic solar cell according to Example 1 significantly increases the external quantum efficiency and light adsorption compared to the organic solar cell according to Comparative Example 1 in the visible ray region, which is a range of about 400 nm to about 700 nm.

Thereby, when the organic solar cell includes a transparent auxiliary layer, it is confirmed that the light efficiency may be improved.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic solar cell comprising:
an anode and a cathode facing each other;
a photoactive layer disposed between the anode and the cathode, and comprising an electron donor and an electron acceptor; and
a transparent auxiliary layer disposed between the anode and the cathode and in contact with the photoactive layer,
wherein the transparent auxiliary layer comprises inorganic nanoparticles and a polymer.

2. The organic solar cell of claim 1, wherein the polymer comprises an insulating polymer.

3. The organic solar cell of claim 2, wherein the polymer comprises one selected from a group consisting of polyethylene glycol, polyethylene oxide, and a combination thereof.

4. The organic solar cell of claim 1, wherein the inorganic nanoparticles comprise one selected from a group consisting of a metal oxide, a semiconductor compound, and a combination thereof.

5. The organic solar cell of claim 4, wherein the inorganic nanoparticles comprise one selected from a group consisting of zinc oxide, titanium oxide, tantalum oxide, tin oxide, niobium oxide, zirconium oxide, lanthanum oxide, copper oxide, strontium oxide, indium oxide, molybdenum oxide, vanadium oxide, tungsten oxide, nickel oxide, iridium oxide, sodium titanate, cadmium sulfide, gallium arsenide, cadmium selenide, lead sulfide, gallium phosphide, cadmium telluride, tellurium cadmium, and a combination thereof.

6. The organic solar cell of claim 5, wherein the transparent auxiliary layer is in contact with the anode, and
the inorganic nanoparticles comprise one selected from a group consisting of molybdenum oxide, vanadium oxide, tungsten oxide, nickel oxide, iridium oxide, lanthanum oxide, copper oxide, strontium oxide, indium oxide, and a combination thereof.

7. The organic solar cell of claim 5, wherein the transparent auxiliary layer is in contact with the cathode, and
the inorganic nanoparticles comprise one selected from a group consisting of zinc oxide, titanium oxide, tantalum oxide, tin oxide, niobium oxide, cadmium sulfide, lead sulfide, indium antimonide, gallium antimonide, aluminum antimonide, cadmium selenide, cadmium telluride, gallium arsenide, aluminum arsenide, indium phosphide, gallium phosphide, aluminum phosphide, and a combination thereof.

8. The organic solar cell of claim 1, wherein an inorganic nanoparticle has a smaller size than a thickness of the transparent auxiliary layer.

9. The organic solar cell of claim 1, wherein the transparent auxiliary layer comprises:
a first transparent auxiliary layer comprising the inorganic nanoparticles; and
a second transparent auxiliary layer comprising the polymer.

10. The organic solar cell of claim 1, wherein the transparent auxiliary layer is a monolayer comprising the inorganic nanoparticles and the polymer.

11. The organic solar cell of claim 1, wherein
a first surface of the transparent auxiliary layer is in contact with the photoactive layer, and
a second surface opposing the first surface of the transparent auxiliary layer is in contact with the anode or the cathode.

12. The organic solar cell of claim 11, further comprising a buffer layer disposed between the photoactive layer and the anode, or between the photoactive layer and the cathode.

13. The organic solar cell of claim 12, wherein the buffer layer comprises a conductive polymer.

14. The organic solar cell of claim 1, wherein the photoactive layer comprises a first photoactive layer and a second photoactive layer, and
the transparent auxiliary layer is disposed between the first photoactive layer and the second photoactive layer.

15. An organic solar cell comprising:
a first electrode;
a buffer layer disposed on a surface of the first electrode, and comprising a conductive polymer;
a photoactive layer disposed on a surface of the buffer layer;
a first transparent auxiliary layer disposed on a surface of the photoactive layer, and comprising inorganic nanoparticles and an insulating polymer; and
a second electrode disposed on a surface of the first transparent auxiliary layer.

16. The organic solar cell of claim 15, wherein
the conductive polymer comprises one selected from a group consisting of poly(3,4-ethylenedioxythiophene): polystyrene sulfonate, polypyrrole, and a combination thereof, and
the insulating polymer comprises one selected from a group consisting of polyethylene glycol, polyethylene oxide, and a combination thereof.

17. The organic solar cell of claim 15, wherein the photoactive layer comprises a first photoactive layer and a second photoactive layer, and
further comprising a second transparent auxiliary layer disposed between the first photoactive layer and the second photoactive layer, and comprising the inorganic nanoparticles and the insulating polymer.

18. A method of manufacturing an organic solar cell, the method comprising:
providing a first electrode;
providing a photoactive layer on a surface of the first electrode;
providing a transparent auxiliary layer comprising inorganic nanoparticles and a polymer on a surface of the photoactive layer; and
providing a second electrode on a surface of the transparent auxiliary layer.

19. The method of claim 18, wherein the polymer comprises an insulating polymer.

20. The method of claim 18, wherein the providing a transparent auxiliary layer is performed by a solution process.

21. The method of claim 18, wherein the providing a transparent auxiliary layer comprises:
providing the inorganic nanoparticles on the surface of the photoactive layer; and
separately providing the polymer on the inorganic nanoparticles.

22. The method of claim 18, wherein providing a transparent auxiliary layer comprises:
providing a solution comprising both the inorganic nanoparticles and the polymer, on the surface of the photoactive layer.
